(19) United States
(12) Patent Application Publication
(10) Pub. No.: US 2007/0193876 A1
(43) Pub. Date: Aug. 23, 2007

(54) Structure for sputtering an anti-reflection layer onto a board at low temperature and a manufacturing method

(76) Inventors: Jau-Jier Chu, Hsin-Chu (TW); Hsu-Fu Hung, Hsin-Chu (TW); I-Wen Lee, Hsin-Chu (TW); Chien-Min Weng, Hsin-Chu (TW); Chao-Lan Lee, Hsin-Chu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/358,090

(22) Filed: Feb. 22, 2006

(51) Int. Cl. C23C 14/32; B32B 9/04

(52) U.S. Cl. 204/192.1; 428/411.1

(57) ABSTRACT

A manufacturing method for sputtering an anti-refection layer onto a board at low temperature has the merits of easily being implemented and easily mass-produced. The manufacturing method is used for sputtering multiple anti-refection layers onto a board. The method can be used for mass-producing anti-reflection panels as the raw material for the photo industry. The method is superior to the manufacturing method for producing nebulization anti-reflection panels. This invention utilizes the anti-reflection characteristics of the board structure that is sputtered and stacked alternatively with high index refraction layers and low index refraction layers. A continuous manufacturing process is adopted. The present invention uses plasma to clean the surface of the boards and adopts a traditional sputtering machine. Therefore, it is convenient for installing and mass-producing high quality material.

### BACKGROUND OF THE INVENTION

1. Field of the Invention

The present invention relates to a structure for sputtering an anti-refection layer onto a board at low temperature and a manufacturing method. In particular, this invention utilizes the anti-reflection characteristics of a board structure that is sputtered and stacked alternatively with a high index refraction layer and a low index refraction layer. A continuous manufacturing process is adopted. The present invention uses plasma to clean the surface of the board and adopts a traditional sputtering machine. Therefore, it is convenient for installing, and mass-producing high quality materials.

2. Description of the Related Art

In the raw photo material production industry, an anti-refection layer panel is the most important raw material. The importance of the raw optical-electrical material production industry is increasing while simultaneously there are growing requests for an improved yield, greater control of the process, reducing costs, and mass-producing for the optical-electrical product. The importance of the raw optical-electrical material production industry is almost the same as the semiconductor industry. The technology for producing anti-refection layer panels is related to a variety of optical-electrical industries, such as LCD, OLED, FED, photo lens, etc. The specifications for an anti-refection layer panel depend on the requirements of each industry. However, when a large dimension panel is produced, it needs to be composed of better raw material because the large dimension panel of the conventional art adopting a nebulization surface structure.

The anti-refection layer panel is a basic raw material for the optical-electrical industry. Almost all high-class panels use an anti-refection layer panel. The anti-refection layer panel and other electronic elements are assembled into an optical-electrical structure as an optical-electrical product to provide a specified function. For the anti-refection layer panel, the desired characteristics are being light pervious and anti-reflection.

Please refer to FIG. 1, which shows a schematic diagram of a product with an anti-reflection lens processed by a nebulization process of the prior art. The LCD 10a has an anti-reflection lens processed by a nebulization process 20a. When the panel is treated with a nebulization process, the panel's light pervious characteristic is affected. It may be acceptable for a general low quality optical-electrical product. However, for a high-resolution product, it will be a big problem due to the need for light pervious and high-resolution characteristics. Therefore, the nebulization process is only suitable for low quality products. Developing a rapid and reliable method for producing sputtering on an anti-refection layer (also known as a multi-layer board) onto a board at low temperatures is necessary. Especially, if the board it is made of macromolecule materials, such as transparent acrylic material (PMMA) or glass.

### SUMMARY OF THE INVENTION

One particular aspect of the present invention is to provide a structure for sputtering an anti-refection layer onto a board at a low temperature and a manufacturing method. The present invention has a stable quality and a convenient manufacturing process. Furthermore, the production machine can be modified from a traditional sputtering machine. The structure for sputtering an anti-refection layer onto a board at low temperature is used in the optical-electrical industry that needs the anti-reflection layer to be the raw material (such as LCD, computer goggles, glasses, high-class display, FED, or photo sensor). It produces the boards that are cheap and has high quality.

Another particular aspect of the present invention is to provide a structure for sputtering an anti-refection layer onto a board at low temperature and a manufacturing method. The present invention provides a structure for sputtering an anti-refection layer onto a board at low temperature via a continuous process. This is achievable due to the board being easily manufactured via a continuous process, and the use of plasma to clean the surface of the board. The present invention adopts the traditional manufacturing process and the peripheral equipment. The manufacturing process is easy and convenient.

The manufacturing method for sputtering an anti-refection layer onto a board at low temperature includes cleaning the surface of the board using the plasma, and sputtering the board with at least one high index refraction layer or at least one low index refraction layer. At least two of each layer are sputtered and stacked alternatively on the board (meaning that there are at least four layers sputtered on the board; generally the number of layers is between four to seven.)

The structure for sputtering an anti-refection layer onto a board at low temperature includes a substrate formed by a board, and at least one high index refraction layer or at least one low index refraction layer formed on the substrate. The high index refraction layers are sputtered and stacked alternatively with the low index refraction layers, and there are at least two layers for both of the high index refraction layer and the low index refraction layer.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a schematic diagram of a product with an anti-reflection lens treated with a nebulization process of the prior art;

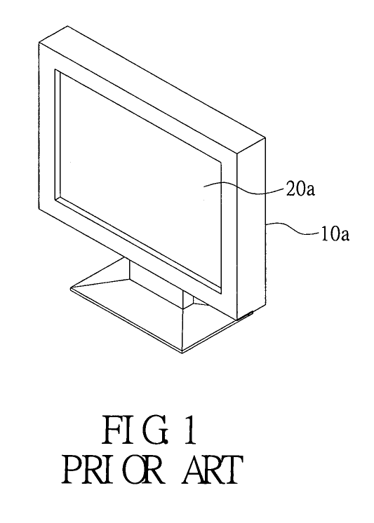

FIG. 2 is a schematic diagram of a production line for producing the structure for sputtering an anti-refection layer onto a board at low temperature of the present invention;

FIG. 3 is a schematic diagram of the structure for sputtering an anti-refection layer onto a board at low temperature of the present invention; and

FIG. 4 is a flow chart of the manufacturing process of the present invention.

### DETAILED DESCRIPTION OF THE PREFERRED EMBODIMENTS

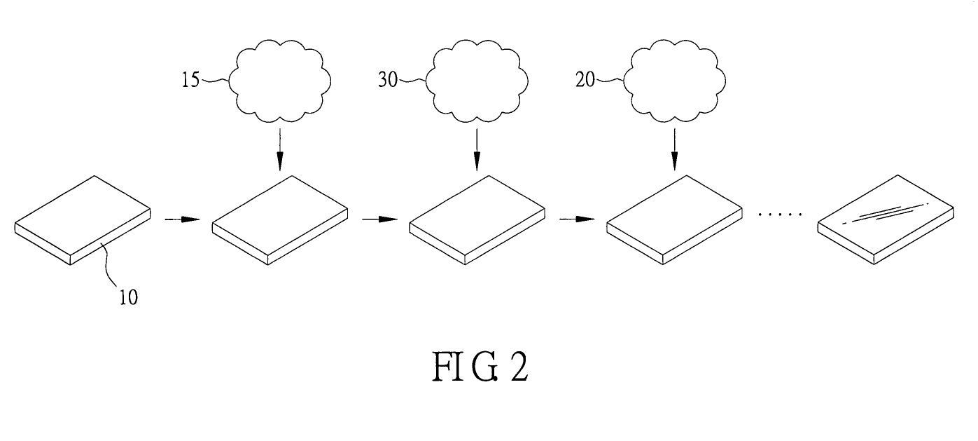

Please refer to FIGS. 2, 3 and 4, which show schematic diagrams of the preferred embodiment of the present invention. A board made of PMMA or glass is continuously manufactured via a continuous production process. The plasma (surface-cleaning plasma 15) is used for cleaning the surface of the board 10 (Step 101). The present invention adopts the traditional manufacturing process and the peripheral equipment with easy manufacturing process (sputtering at least one high index refraction layer 22 or at least one low index refraction layer 32) to combine each manufacturing process together (Step 103). The high index refraction layer 22 is made of metal oxide plasma, and the low index refraction layer 32 is made of non-metal oxide plasma.

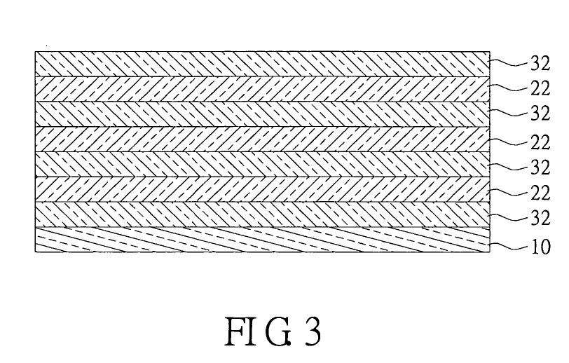

FIG. 2 shows a schematic diagram of a production line for producing the structure for sputtering an anti-refection layer onto a board at low temperature of the present invention. Firstly, the PMMA board is inputted (at the left side of FIG. 2). Then, plasma (surface-cleaning plasma 15) cleans the surface of the board 10 (the second step from the left side of FIG. 2). At least one layer of metal oxide 20 or non-metal oxide 30 is sputtered on the board 10 (the third and fourth step from the left side of FIG. 2). In this embodiment, at least two layers of SiO (a raw material being Si, and an oxide film being formed during the sputtering process) and at least two layers of ZnO (an oxide film is formed during the sputtering process). As shown in the FIG. 3, there are at least four layers. Generally, there are four to seven layers. In this embodiment, the present invention is very suitable for the conventional production line with a sputtering process. An engineer only needs to modify a semi-conductor production line that is used for processing chips. The modified production line can be used in the continuous sputtering process to produce the anti-refection multi-layer panels of the present invention.

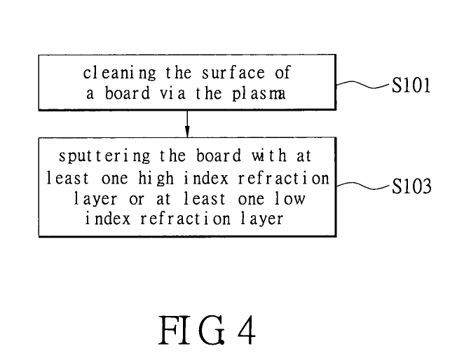

Please refer to FIG. 4, the manufacturing method for sputtering an anti-refection layer onto a board at low temperature of the present invention includes cleaning the surface of the board 10 with plasma (S101), and sputtering the board 10 with at least one high index refraction layer or at least one low index refraction layer (S103). There are at least two layers of each and the high index refraction layer and the low index refraction layer are sputtered and stacked alternatively on the board (this means there are at least four layers sputtered on the board, generally the number of the layers is between four to seven).

The board 10 is sputtered via a continuous workstation manufacturing process. Therefore, the delay time between the workstations is controlled within a predetermined period. The board 10 is made of macromolecule materials or glass. The high index refraction layer 22 is made of metal oxide, and the low index refraction layer 32 is made of non-metal oxide. The high index refraction layer 22 is made of ITO, Nb₂O₅ or ZnO, and the low index refraction layer 32 is made of SiO₂. The sputtering process for the board 10 is implemented in a space within a specified cleanness level (the surface of the workpiece must be neat). The board 10 is transported between the workstations via a transporting belt or an auto cart (similar to the semiconductor manufacturing process). Before the step of cleaning the surface of the board, the present invention includes a step of manufacturing the board 10 via a pressing process (for controlling the dimension of the workpiece). The bottom layer and the top layer on the board 10 are low index refraction layers 32.

The structure for sputtering an anti-refection layer onto a board at low temperature of the present invention includes a substrate formed by a board 10, and at least one high index refraction layer 22 or at least one low index refraction layer formed 32 on the substrate. The high index refraction layers 22 are sputtered and stacked alternatively with the low index refraction layers 32, and there are at least two high index refraction layers 22 and two low index refraction layers 32.

The characteristics of the present invention provide a structure for sputtering an anti-refection layer onto a board at low temperature and a manufacturing method. The present invention has a table quality and a convenient manufacturing process. Furthermore, the production machine can be modified from a traditional sputtering machine. The structure for sputtering an anti-refection layer onto a board at low temperature is used in the optical-electrical industry that uses high quality panels as the raw material (such as LCD, computer goggles, glasses, high-class display, FED, or optical-electrical sensor). It has the characteristics of being cheap and producing and high quality panels.

The present invention has the following merits:

1. The new manufacturing process can be easily implemented, and the cost of new equipment is low and the requirement of the technology is also low.

2. It uses a continuous manufacturing process. Therefore, production speed is high.

3. The present invention can be used in optical-electrical products that need high quality anti-reflection film, and can be implemented via the conventional manufacturing process.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A manufacturing method for sputtering an anti-refection layer onto a board at low temperature, comprising:
cleaning the surface of a board using plasma; and
sputtering the board with at least one high index refraction layer or at least one low index refraction layer;
wherein, at least two high index refraction layers and at least two low index refraction layers are sputtered and stacked alternatively on the board.

2. The manufacturing method for sputtering an anti-refection layer onto a board at low temperature as claimed in claim 1, wherein the board is sputtered via a continuous workstation manufacturing process to control the delay time between the workstations within a predetermined period.

3. The manufacturing method for sputtering an anti-refection layer onto a board at low temperature as claimed in claim 1, wherein the board is made of macromolecule materials or glass.

4. The manufacturing method for sputtering an anti-refection layer onto a board at low temperature as claimed in claim 1, wherein the high index refraction layer is made of metal oxide, and the low index refraction layer is made of non-metal oxide.

5. The manufacturing method for sputtering an anti-refection layer onto a board at low temperature as claimed in claim 1, wherein the high index refraction layer is made of ITO, Nb₂O₅ or ZnO and the low index refraction layer is made of SiO₂.

6. The manufacturing method for sputtering an anti-refection layer onto a board at low temperature as claimed in claim 1, wherein the sputtering process for the board is implemented in a space with a cleanness level being within a specified value.

7. The manufacturing method for sputtering an anti-refection layer onto a board at low temperature as claimed in claim 1, wherein the board is transported between the workstations via a transporting belt or an auto cart.

8. The manufacturing method for sputtering an anti-refection layer onto a board at low temperature as claimed in claim 1, further comprising a step of manufacturing the board via a pressing process.

9. The manufacturing method for sputtering an anti-refection layer onto a board at low temperature as claimed in claim 1, wherein the bottom layer is the low index refraction layers.

10. A structure for sputtering an anti-refection layer onto a board at low temperature of the present invention, comprising:
a substrate formed by a board; and
at least one high index refraction layer or at least one low index refraction layer formed on the substrate;
wherein the high index refraction layers are sputtered and stacked alternatively with the low index refraction layers, and there are at least two high index refraction layers and at least two low index refraction layers.

11. The structure for sputtering an anti-refection layer onto a board at low temperature as claimed in claim 10, wherein the board is made of macromolecule materials or glass.

12. The structure for sputtering an anti-refection layer onto a board at low temperature as claimed in claim 10, wherein the high index refraction layer is made of metal oxide, and the low index refraction layer is made of non-metal oxide.

13. The structure for sputtering an anti-refection layer onto a board at low temperature as claimed in claim 10, wherein the high index refraction layer is made of ITO, Nb₂O₅ or ZnO and the low index refraction layer is made of SiO₂.

14. The structure for sputtering an anti-refection layer onto a board at low temperature as claimed in claim 10, wherein the bottom layer and the top layer on the board are the low index refraction layers.
